(19) United States
(12) Patent Application Publication
(10) Pub. No.: US 2025/0050657 A1
(43) Pub. Date: Feb. 13, 2025

(54) APPARATUS FOR MANUFACTURING DISPLAY DEVICE

(71) Applicant: SAMSUNG DISPLAY CO., LTD., YONGIN-SI (KR)

(72) Inventors: Jae Gi YOO, Yongin-si (KR); Byung Su KIM, Yongin-si (KR)

(21) Appl. No.: 18/630,247

(22) Filed: Apr. 9, 2024

(30) Foreign Application Priority Data
Aug. 7, 2023 (KR) 10-2023-0102644

(51) Int. Cl. B41J 3/28; B41J 2/045; B41J 3/407; B41J 11/06

(52) U.S. Cl. CPC B41J 3/28; B41J 2/04541; B41J 2/04586; B41J 3/407; B41J 11/06

(57) ABSTRACT

An apparatus for manufacturing a display device includes: a stage; an ejection head overlapping the stage, wherein the ejection head includes a main body part and a nozzle part, wherein the main body part houses ink, and the nozzle part includes a nozzle tip and a first housing surrounding the nozzle tip; and a detection sensor interposed between the nozzle tip and the first housing.

### CROSS-REFERENCE TO RELATED APPLICATION

This application claims priority under 35 U.S.C. § 119 to Korean Patent Application No. 10-2023-0102644, filed on Aug. 7, 2023, in the Korean Intellectual Property Office, the disclosure of which is incorporated by reference herein in its entirety.

### TECHNICAL FIELD

Embodiments of the present invention relate to an apparatus for manufacturing a display device.

### DISCUSSION OF THE RELATED ART

With the advancement of the information society, there is a growing demand for display devices, which are for displaying images, in various forms. For example, display devices may take the form of flat-panel display devices such as a liquid crystal display (LCD), a field-emission display (FED), a light-emitting display panel, etc. Light-emitting display devices may include organic light-emitting display devices including organic light-emitting diode (OLED) components or light-emitting diode (LED) display devices including inorganic LEDs.

In addition, during the manufacture of a display device, processes such as inkjet, dispenser, and screen printing processes can be utilized. The dispenser process, in particular, may accurately and swiftly dispensing high-viscosity ink, preventing ink overflow when using high-viscosity ink, and facilitating easy adjustment of the volume of ink discharge.

### SUMMARY

According to embodiments of the present invention, an apparatus for manufacturing a display device includes: a stage; an ejection head overlapping the stage, wherein the ejection head includes a main body part and a nozzle part, wherein the main body part houses ink, and the nozzle part includes a nozzle tip and a first housing surrounding the nozzle tip; and a detection sensor interposed between the nozzle tip and the first housing.

In embodiments of the present invention, the detection sensor surrounds the nozzle tip.

In embodiments of the present invention, the detection sensor is interposed between the nozzle tip and the first housing in a direction different from an extension direction of the nozzle tip.

In embodiments of the present invention, the detection sensor is disposed outside of the main body part.

In embodiments of the present invention, the detection sensor has an annular shape.

In embodiments of the present invention, the detection sensor is pressure sensor.

In embodiments of the present invention, the detection sensor includes a first electrode, a second electrode, and a piezoelectric body disposed between the first and second electrodes.

In embodiments of the present invention, the second electrode surrounds the piezoelectric body, and the piezoelectric body surrounds the first electrode.

In embodiments of the present invention, a direction in which the first electrode, the piezoelectric body, and the second electrode are stacked is perpendicular to an extension direction of the nozzle tip.

In embodiments of the present invention, the direction in which the first electrode, the piezoelectric body, and the second electrode are stacked is the same as the extension direction of the nozzle tip.

In embodiments of the present invention, the apparatus further includes: a head driver moving the ejection head; and a controller controlling an operation of the ejection head, wherein the control device includes: a signal processing circuit receiving a first signal from the detection sensor; and a driving control circuit receiving a second signal from the signal processing unit, and wherein the driving control circuit provides a third signal to the head driving unit.

In embodiments of the present invention, the first signal includes information regarding a contact status of the nozzle tip with an object.

In embodiments of the present invention, the second signal includes information regarding at least one of a contact position or contact intensity of the nozzle tip.

In embodiments of the present invention, the third signal is for controlling the ejection head.

In embodiments of the present invention, the apparatus further includes: an output device receiving an output signal from the signal processing circuit, wherein the output device outputs at least one of an image or sound upon receiving the output signal.

In embodiments of the present invention, the apparatus further includes: an image sensor capturing an image of the ejection head, wherein the output device receives an image data signal from the image sensor by receiving the output signal from the signal processing circuit.

In embodiments of the present invention, the apparatus further includes: a first nozzle tube connecting the main body part and the nozzle part to each other, wherein the nozzle tip includes a coupling portion, which is coupled to the first nozzle tube.

In embodiments of the present invention, the nozzle part further includes a sealing portion, which is disposed in a receiving portion of the main body part, and the sealing portion surrounds the first nozzle tube.

In embodiments of the present invention, the nozzle part further includes a first fixing portion, which is disposed between the first housing and the nozzle tip, and the detection sensor is interposed between the first fixing portion and the nozzle tip.

According to embodiments of the present invention, an apparatus for manufacturing a display device includes: an ejection head including a nozzle tip and a first housing, which surrounds the nozzle tip; a detection sensor interposed between the nozzle tip and the first housing, wherein the detection sensor surrounds the nozzle tip; and an ink supply line connected to the ejection head.

### BRIEF DESCRIPTION OF THE DRAWINGS

The above and other aspects and features of the present invention will become more apparent by describing in detail embodiments thereof with reference to the attached drawings, in which:

FIG. 1 is a perspective view of an apparatus for manufacturing a display device according to an embodiment of the present invention;

FIG. 2 is a side view of an ejection head of the apparatus for manufacturing a display device according to an embodiment of the present invention;

FIG. 3 is an schematic cross-sectional perspective view of area A of FIG. 2;

FIG. 4 is another schematic cross-sectional perspective view of area A of FIG. 2;

FIG. 5 is a cross-sectional perspective view of a detection sensor according to an embodiment of the present invention;

FIG. 6 is a cross-sectional view of area B of FIG. 4;

FIG. 7 is a block diagram illustrating an operating method of a control device according to an embodiment of the present invention;

FIG. 8 is a schematic cross-sectional perspective view illustrating an operating method of the display device according to an embodiment of the present invention;

FIG. 9 is a cross-sectional perspective view of a nozzle part of an ejection head of an apparatus for manufacturing a display device according to an embodiment of the present invention;

FIG. 10 is a cross-sectional view of the nozzle part of FIG. 9;

FIG. 11 is a cross-sectional view of a detection sensor according to an embodiment of the present invention;

FIG. 12 is a cross-sectional view of area C of FIG. 10;

FIG. 13 is a cross-sectional perspective view of a nozzle part of an ejection head of an apparatus for manufacturing a display device according to an embodiment of the present invention;

FIG. 14 is a cross-sectional view of a nozzle part of an ejection head of an apparatus for manufacturing a display device according to an embodiment of the present invention;

FIG. 15 is a cross-sectional view of area D of FIG. 14; and

FIG. 16 is a cross-sectional perspective view illustrating how to manufacture a display device using an apparatus for manufacturing a display device according to an embodiment of the present invention.

### DETAILED DESCRIPTION OF EMBODIMENTS

The present invention will now be described more fully hereinafter with reference to the accompanying drawings. The present invention may, however, be embodied in different forms and should not be construed as limiting of the present invention.

It will also be understood that when a layer is referred to as being “on” another layer or substrate, it can be directly on the other layer or substrate, or intervening layers may also be present. The same reference numbers may indicate the same components throughout the specification and drawings, and thus, repetitive descriptions may be omitted.

Hereinafter, embodiments of the present invention will be described in detail with reference to the accompanying drawings.

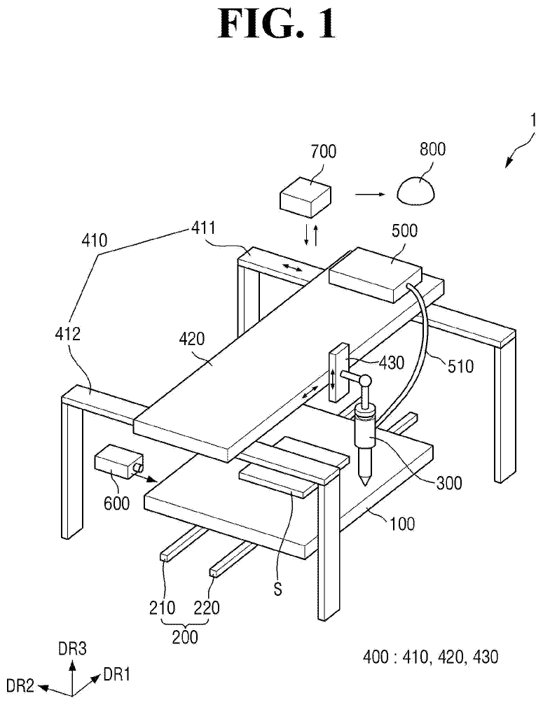

FIG. 1 is a perspective view of an apparatus for manufacturing a display device according to an embodiment of the present invention.

Referring to FIG. 1, an apparatus 1 for manufacturing a display device may eject ink onto a target substrate S. The apparatus 1 may be an ink ejection apparatus for ejecting ink. For example, the apparatus 1 may be a dispenser apparatus for ejecting ink through a nozzle.

The apparatus 1 may be used to fabricate a display device. Examples of the display device include a liquid crystal display (LCD) device, an organic light-emitting display device, and an inorganic light-emitting display device, but the present invention is not limited thereto.

The apparatus 1 may include a stage 100, a stage driving unit 200, an ejection head 300, a head driving unit 400, an ink supply device 500, a vision device 600, a control device 700, and an output device 800.

The stage 100 may provide a space for accommodating the target substrate S to be provided thereon. Here, the target substrate S may be a display device, but the present invention is not limited thereto. The stage 100 may have a flat shape. The planar configuration of the stage 100 may be similar to the planar configuration of the target substrate S. For example, the planar configuration of the stage 100 may be approximately rectangular, but the present invention is not limited thereto.

The stage driving unit (or a stage driver) 200 may move the stage 100. For example, the stage driving unit 200 may provide driving force to the stage 100 to move the stage 100 along a first direction DR1. The stage 100 may be disposed on the stage driving unit 200.

The first direction DR1 and a second direction DR2 are horizontal directions that intersect with each other. For example, the first and second directions DR1 and DR2 may be mutually orthogonal. A third direction DR3 intersects with the first and second directions DR1 and DR2, and may be a vertical direction that is substantially perpendicular to the first and second directions DR1 and DR2. In this specification, a first side in each of the first, second, and third directions DR1, DR2, and DR3 may indicate the direction pointed to by the arrow for the corresponding direction on each of the accompanying diagrams, while a second side in each of the first, second, and third directions DR1, DR2, and DR3 may indicate the opposite direction to that pointed to by the arrow for the corresponding direction. When not explicitly mentioned, each of the first, second, and third directions DR1, DR2, and DR3 may indicate both sides in the corresponding direction.

In embodiments of the present invention, the stage driving unit 200 may include first and second rails 210 and 220. The first and second rails 210 and 220 may extend along the first direction DR1. The first and second rails 210 and 220 may be spaced apart from each other along the second direction DR2.

In embodiments of the present invention, the stage driving unit 200 may include an actuator and/or a motor.

The ejection head 300 may eject ink onto the target substrate S. The ejection head 300 may eject ink onto a first surface (e.g., a top surface) of the target substrate S, which is fixed on a first side, in the third direction DR3, of the stage 100. The ejection head 300 may be a dispenser capable of ejecting a single droplet of liquid ink per ejection event.

The ejection head 300 may be disposed on the first side, in the third direction DR3, of the stage 100. For example, the ejection head 300 may face the top surface of the stage 100. For example, the ejection head 300 may be positioned above the stage 100 in the third direction DR3.

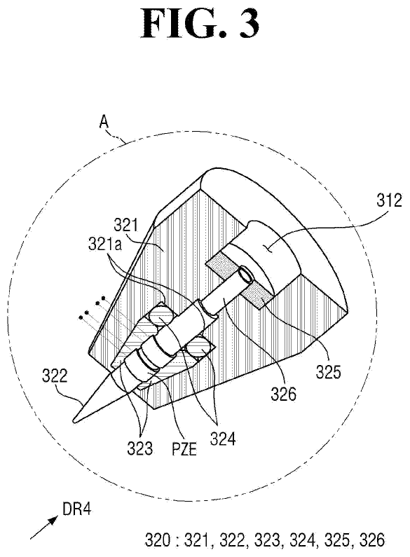

The ejection head 300 may include detection sensors (“PZE” of FIG. 3). As the apparatus 1 includes the detection sensors PZE, the apparatus 1 can automatically control the position of the ejection head 300. The detection sensors PZE will be described later with reference to FIG. 3.

The head driving unit (or head driver) 400 may move the ejection head 300. For example, the head driving unit 400 may provide driving force to the ejection head 300 to move the ejection head 300 in the first, second, and third directions DR1, DR2, and DR3.

In embodiments of the present invention, the head driving unit 400 may include a first horizontal head driver 410, a second horizontal head driver 420, and a vertical head driver 430.

The second horizontal head driver 420 may be disposed on the first horizontal head driver 410. For example, the second horizontal head driver 420 may be positioned on the surface of the first horizontal head driver 410. For example, the second horizontal head driver 420 may be disposed on a top surface of the first horizontal head driver 420. The vertical head driver 430 may be disposed on the second horizontal head driver 420. For example, the vertical head driver 430 may be positioned on the surface of the second horizontal head driver 420. For example, the vertical head driver 430 may be positioned on a second side, in the second direction DR2, of the second horizontal head driver 420.

The first horizontal head driver 410 may extend in the second direction DR2. The first horizontal head driver 410 may reciprocate the second horizontal head driver 420 in the second direction DR2. Consequently, the ejection head 300 can reciprocate in the second direction DR2. For example, the first horizontal head driver 410 may include an actuator and/or motor.

The second horizontal head driver 420 may extend in the first direction DR1. The second horizontal head driver 420 may reciprocate the vertical head driver 430 in the first direction DR1. Consequently, the ejection head 300 can reciprocate in the first direction DR1. For example, the second horizontal head driver 420 may include an actuator and/or motor.

The vertical head driver 430 may extend in the third direction DR3. The vertical head driver 430 may reciprocate the ejection head 300 in the third direction DR3. Consequently, the ejection head 300 can reciprocate in the third direction DR3. For example, the vertical head driver 430 may include an actuator and/or motor.

In embodiments of the present invention, the first horizontal head driver 410 may include first and second supports 411 and 412. The first and second supports 411 and 412 may be spaced apart from each other along the first direction DR1. Each of the first and second supports 411 and 412 may include a horizontal support portion extending in the second direction DR2 and vertical support portions extending in the third direction DR3. For example, a horizontal support portion may be disposed on two vertical support portions.

The ink supply device 500 may supply ink to the ejection head 300. For example, the ink supply device 500 may supply ink to the ejection head 300 through an ink supply line 510. For example, the ink supply device 500 may include a pump and a storage container. For example, the ink supply device 500 may include a stirring part to maintain the viscosity of the ink.

The vision device 600 may capture images of the stage 100, the target substrate S, and the ejection head 300. The vision device 600 may collect and provide image data for inspecting the positions of the stage 100, the target substrate S, and the ejection head 300. For example, the vision device 600 may collect and provide image data to confirm whether there is contact between a nozzle part 320 of the ejection head 300 and the stage 100 or between the nozzle part 320 and the target substrate S. For example, the vision device 600 may include at least one of an image sensor, a memory, processor, an input circuit, or an output circuit.

The vision device 600 may be disposed on one side of the stage 100. For example, the vision device 600 may be positioned at the same height as the stage 100 in the third direction DR3. The vision device 600 may be disposed on a first side, in the second direction DR2, of the stage 100, but the present invention is not limited thereto. In addition, the vision device 600 may be disposed on a second side, in the second direction DR2, of the stage 100, on a first side, in the first direction DR1, of the stage 100, and/or on a second side, in the first direction DR1, of the stage 100.

The control device (or controller) 700 may control the position of the ejection head 300. For example, the control device 700 may receive a contact signal CS from the detection sensors PZE of the ejection head 300 and adjust the position of the ejection head 300 based on the contact signal CS.

The control device 700 may provide an output signal to the output device 800 to output image data or sound data. For example, the control device 700 may provide the output signal to the output device 800 to receive image data from the vision device 600 and display the received image data.

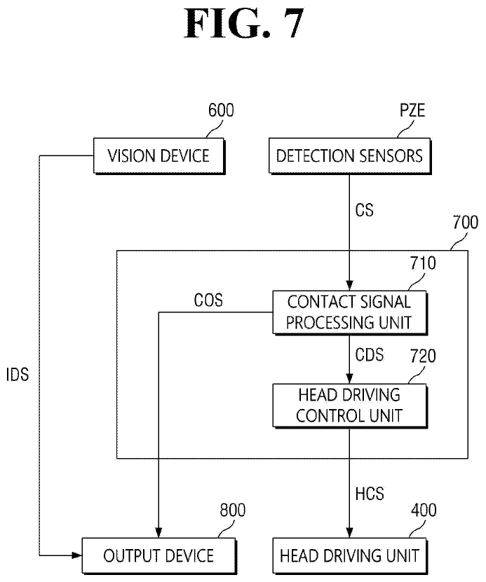

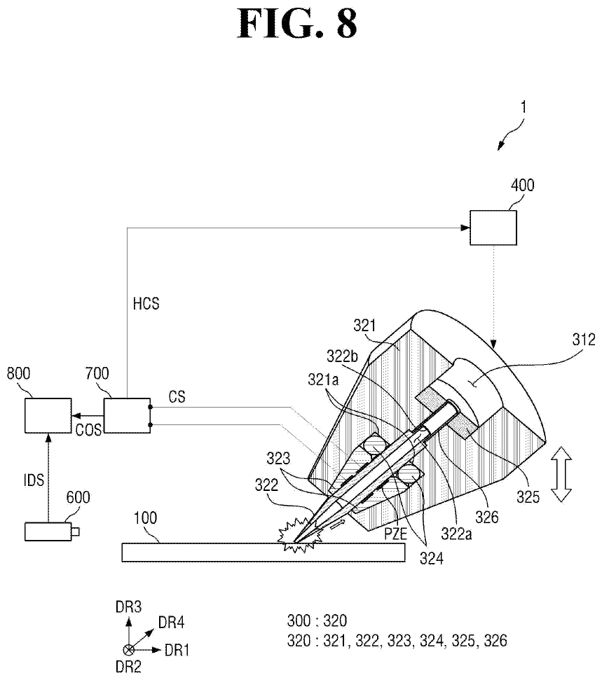

The operation of the control device 700 will be described later with reference to FIGS. 7 and 8.

The output device 800 may output information regarding the current state of the apparatus 1 in a form that is recognizable by a user, such as an image or sound. For example, the output device 800 may output image data that is received from the vision device 600 to the outside.

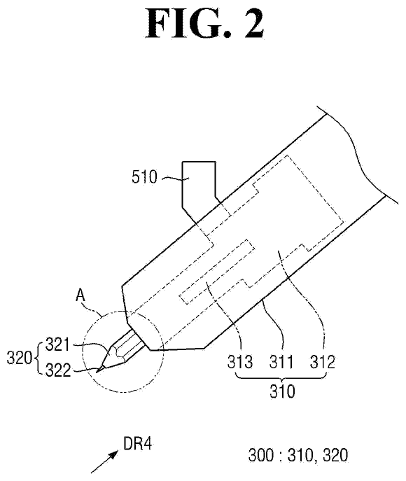

FIG. 2 is a side view of an ejection head of the apparatus for manufacturing a display device according to an embodiment of the present invention.

Referring to FIGS. 1 and 2, the ejection head 300 may include a main body part 310 and the nozzle part 320.

The main body part 310 may be connected to the head driving unit 400. For example, the main body part 310 may be connected to the vertical head driver 430. Accordingly, the ejection head 300 can move in the first, second, and third directions DR1, DR2, and DR3 by receiving driving force from the head driving unit 400.

The main body part 310 may be connected to the ink supply line 510. The main body part 310 may include ink from the ink supply device 500 through the ink supply line 510.

The main body part 310 may include a first housing 311, a receiving portion 312, and a stirring part 313.

The first housing 311 may form the exterior of the main body part 310. The first housing 311 may surround the receiving portion 312 and the stirring part 313. The first housing 311 may at least partially surround the nozzle part 320. The first housing 311 may include an opening that can be connected to the ink supply line 510.

The receiving portion 312 may accommodate ink introduced from the ink supply line 510 into the main body part 310. The receiving portion 312 may be spatially connected to the ink supply line 510 and the nozzle part 320. The receiving portion 312 may extend in a fourth direction DR4.

In this specification and the accompanying diagrams, the fourth direction DR4 may refer to the same direction as the extension direction of the main body part 310 or the receiving portion 312, and may also refer to the same direction as the extension direction of a nozzle tube from which ink is ejected. In addition, in embodiments of the present invention, the fourth direction DR4 may differ from the first, second, and third directions DR1, DR2, and DR3. In addition, the fourth direction DR4 may intersect the first, second, and third directions DR1, DR2, and DR3 depending on the degree to which the ejection head 300 is inclined.

The stirring part 313 may be placed inside the receiving portion 312. In embodiments of the present invention, the stirring part 313 may include a rotating roller. The stirring part 313 may regulate the viscosity of the ink through the rotation of the roller. For example, the roller that is included in the stirring part 313 may rotate at a consistent frequency per unit of time to maintain the viscosity of the ink. The stirring part 313 may increase the rotational speed of the roller per unit of time when the viscosity of ink becomes higher, and conversely, decrease the rotational speed of the roller per unit of time when the viscosity of the ink becomes lower.

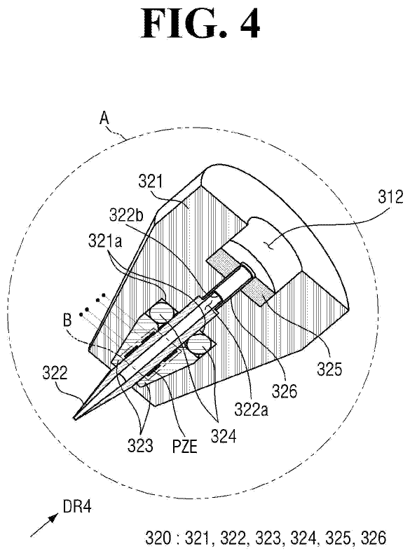

The nozzle part 320 may be disposed on one side of the main body part 310. For example, the nozzle part 320 may be disposed on a second side, in the fourth direction DR4, of the main body part 310. The nozzle part 320 may include a second housing 321 and a nozzle tip 322. The nozzle part 320 will hereinafter be described with reference to FIGS. 3 and 4.

FIG. 3 is an schematic cross-sectional perspective view of area A of FIG. 2. FIG. 4 is a schematic cross-sectional perspective view of area A of FIG. 2.

Referring to FIGS. 3 and 4 and further to FIG. 2, the nozzle part 320 may include the second housing 321, the nozzle tip 322, a first fixing portion 323, a second fixing portion 324, a sealing portion 325, and a first nozzle tube 326.

The second housing 321 may form the exterior of the nozzle part 320. The second housing 321 can surround at least a portion of the nozzle tip 322, the first fixing portion 323, the second fixing portion 324, the sealing portion 325, and at least a portion of the first nozzle tube 326. The second housing 321 may be at least partially surrounded by the first housing 311.

The nozzle tip 322 may extend in the fourth direction DR4. The nozzle tip 322 may be surrounded by the second housing 321, the first fixing portion 323, and the second fixing portion 324.

In embodiments of the present invention, the nozzle tip 322 may be attached to or detached from the second housing 321. For example, the nozzle tip 322 may be interposed within an empty space that is defined by the first and second fixing portions 323 and 324. The nozzle tip 322 may be coupled within the second housing 321 by the first and second fixing portions 323 and 324 and may be separated from the second housing 321 to the outside by applying a force toward a second side in the fourth direction DR4. In addition, when the nozzle tip 322 is coupled to the second housing 321, one end portion, in the fourth direction DR4, of the nozzle tip 322 may be interposed between first stepped portions 321a of the second housing 321. Thus, the replacement of the nozzle tip 322 can be facilitated.

The nozzle tip 322 may include a second nozzle tube 322a, which extends in the fourth direction DR4. The second nozzle tube 322a may serve as a passage that penetrates the nozzle tip 322 in the fourth direction DR4. The second nozzle tube 322a may provide a pathway through which ink that has moved from the main body part 310 to the nozzle part 320 can be ejected through the end portion (or the tip) of the nozzle part 320. The second nozzle tube 322a may be connected to the first nozzle tube 326.

In embodiments of the present, the nozzle tip 322 may include a coupling portion 322b. The coupling portion 322b may protrude from a first-side end portion, in the fourth direction DR4, of the nozzle tip 322 toward a first side in the fourth direction DR4. The outer diameter of the coupling portion 322b may be smaller than the outer diameter of the nozzle tip 322. When the nozzle tip 322 is coupled to the second housing 321, the coupling portion 322b may be surrounded by the first nozzle tube 326. For example, the coupling portion 322b may be inserted into the first nozzle tube 326. In this example, the outer diameter of the coupling portion 322b and the inner diameter of the first nozzle tube 326 may be substantially the same as each other. In a plan view from the fourth direction DR4, the shape of the coupling portion 322b may be identical to the shapes of the nozzle tip 322 and the first nozzle tube 326.

The first and second fixing portions 323 and 324 may be arranged to surround the nozzle tip 322. The second fixing portion 324 may be disposed on a first side, in the fourth direction DR4, of the first fixing portion 323. The second fixing portion 324 may be disposed between the receiving portion 312 of the main body part 310 and the first fixing portion 323. For example, the first fixing portion 323 may have a hollow cone shape, and the second fixing portion 324 may have a hollow donut shape.

The first and second fixing portions 323 and 324 may facilitate the attachment and detachment of the nozzle tip 322. For example, the second fixing portion 324 may include a roller ball, and while the roller ball rotates, the nozzle tip 322 can easily move in the fourth direction DR4 within the second housing 321. In addition, as the first fixing portion 323 extends in the fourth direction DR4, the first fixing portion 323 can increase its contact surface that is has with the nozzle tip 322 and can thereby increase the fixation force for the nozzle tip 322.

The first nozzle tube 326 may connect the receiving portion 312 of the main body part 310 and the second nozzle tube 322a of the nozzle tip 322 to each other. The first nozzle tube 326 may serve as a pathway through which ink can move from the receiving portion 312 of the main body part 310 to the second nozzle tube 322a of the nozzle tip 322.

The first nozzle tube 326 is illustrated as a separate component from the second housing 321, but the present invention is not limited thereto. For example, the first nozzle tube 326 may be an integral component that is physically coupled with the second housing 321. The first nozzle tube 326 may be an inner tube that is located within the second housing 321.

The sealing portion 325 may be disposed within the receiving portion 312 of the main body part 310. The sealing portion 325 may be arranged to surround at least a portion of the first nozzle tube 326. The sealing portion 325 can increase the coupling force between the first nozzle tube 326 and the receiving portion 312 of the main body part 310. The first nozzle tube 326 may protrude into the receiving portion 312, and the sealing portion 325 may be arranged to surround the protruding part of the first nozzle tube 326. For example, the sealing portion 325 may completely surround the protruding part of the first nozzle tube 326. Consequently, ink within the receiving portion 312 can smoothly move to the first nozzle tube 326.

The apparatus 1 may further include the detection sensors PZE, which are disposed between the nozzle tip 322 and the second housing 321 or between the nozzle tip 322 and the first fixing portion 323. For example, the detection sensors PZE may be disposed within the second housing 321.

The detection sensors PZE may surround the nozzle tip 322. Two detection sensors PZE are illustrated as being spaced apart from each other in the fourth direction DR4, but the present invention is not limited thereto. In addition, one detection sensor PZE or three or more detection sensors PZE may be provided. For example, as illustrated in FIG. 3, the detection sensors PZE may have a tube shape. As another example, the detection sensors PZE may have an annular shape.

The detection sensors PZE may be disposed between the first fixing portion 323 and the nozzle tip 322. For example, the first fixing portion 323 may surround the detection sensors PZE, and the detection sensors PZE may surround the nozzle tip 322. The detection sensors PZE may be interposed between the second housing 321 and the nozzle tip 322 in a direction different from the extension direction of the nozzle tip 322. For example, the detection sensors PZE may be interposed between the second housing 321 and the nozzle tip 322 in a direction that is perpendicular to the fourth direction DR4.

In embodiments of the present invention, the detection sensors PZE may be pressure sensors. For example, the detection sensors PZE may be pressure sensors such as piezoelectric sensors, piezoresistive sensors, or capacitive sensors.

As the apparatus 1 includes the detection sensors PZE around the nozzle tip 322, the apparatus 1 can detect any impact that is applied to the nozzle tip 322.

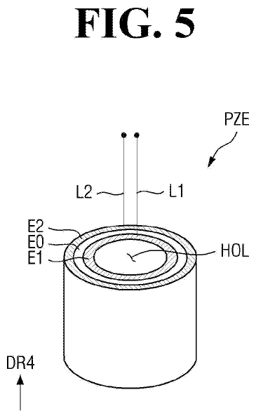

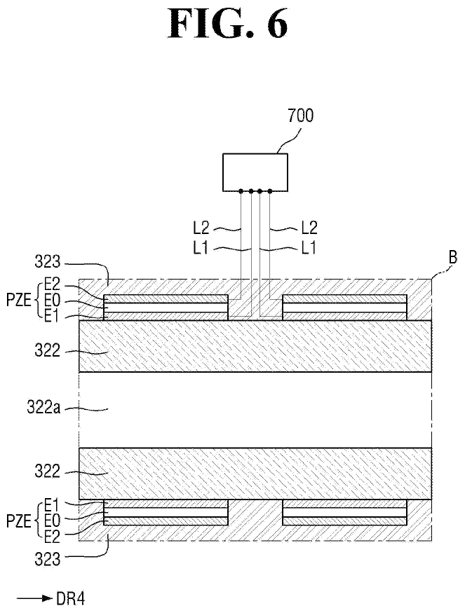

FIG. 5 is a cross-sectional perspective view of a detection sensor according to an embodiment of the present invention. FIG. 6 is a cross-sectional view of area B of FIG. 4.

Referring to FIGS. 5 and 6 and further to FIGS. 3 and 4, each of the detection sensors PZE may include a first electrode E1, a piezoelectric body E0, a second electrode E2, and a through hole HOL.

As illustrated in FIG. 5, the second electrode E2 may surround the piezoelectric body E0, and the piezoelectric body E0 may surround the first electrode EL. The first electrode E1 may surround the through hole HOL. In other words, the piezoelectric body E0 may be interposed between the first and second electrodes E1 and E2. The nozzle tip 322 may be disposed inside the through hole HOL.

The maximum diameter of the second electrode E2 may be larger than the maximum diameter of the piezoelectric body E0, and the maximum diameter of the piezoelectric body E0 may be larger than the maximum diameter of the first electrode EL. The maximum diameter of the first electrode E1 may be larger than the maximum diameter of the through hole HOL.

In embodiments of the present invention, the first and second electrodes E1 and E2 may include a conductive material. For example, each of the first and second electrodes E1 and E2 may include a transparent conductor such as indium tin oxide (ITO) or indium zinc oxide (IZO), an opaque metal, a conducting polymer, or carbon nanotube (CNT).

The piezoelectric body E0 may include a piezoelectric material. For example, the piezoelectric body E0 may include at least one of lead zirconate titanate ceramic (PZT), polyvinylidene fluoride (PVDF), or electrically active polymer (EAP).

As illustrated in FIG. 6, in a cross-section view taken along the fourth direction DR4, the first fixing portion 323 may be disposed on the second electrode E2, and the second electrode E2 may be disposed on the piezoelectric body E0. The piezoelectric body E0 may be disposed on the first electrode E1, and the first electrode E1 may be disposed on the nozzle tip 322.

The direction in which the first electrode E1, the piezoelectric body E0, and the second electrode E2 are stacked may differ from the extension direction of the nozzle tip 322. For example, the first electrode E1, the piezoelectric body E0, and the second electrode E2 may be stacked in a direction that is perpendicular to the fourth direction DR4.

The detection sensors PZE may detect changes in pressure that are caused by external impact applied to the nozzle tip 322. The detection sensors PZE may sense pressure that is applied along the stacking direction of the first electrode E1, the piezoelectric body E0, and the second electrode E2. For example, the detection sensors PZE may detect pressure that is applied in multiple directions. For example, the detection sensors PZE may detect pressure that is applied in the direction that is perpendicular to the fourth direction DR4. Pressure applied along the stacking direction of the first electrode E1, the piezoelectric body E0, and the second electrode E2 may lead to variations in the thickness of the piezoelectric body E0. These thickness changes may result in the generation of positive and negative voltages in the first and second electrodes E1 and E2, respectively. The positive voltage generated in the first electrode E1 may be transmitted to the control device 700 through a first line L1, while the negative voltage generated in the second electrode E2 can be conveyed to the control device 700 through a second line L2.

FIG. 7 is a block diagram illustrating an operating method of a control device according to an embodiment of the present invention. FIG. 8 is a schematic cross-sectional perspective view illustrating an operating method of the display device according to an embodiment of the present invention.

Referring to FIGS. 7 and 8, the control device 700 may control the operation of the ejection head 300 when contact between the nozzle tip 322 and other components is detected through the detection sensors PZE.

For example, as illustrated in FIG. 8, before the ejection of ink, the nozzle tip 322 needs to be in contact with the top surface of the stage 100 to set the reference position, in the third direction DR3, of the ejection head 300. If the user manually manipulates the height of the ejection head 300 in the third direction DR3 by using the vision device 600, the ejection head 300 may excessively move towards the stage 100, potentially causing damage to the nozzle tip 322.

The apparatus 1 can minimize damage to the nozzle tip 322 by adjusting the position of the ejection head 300 through the control device 700 to stop the ejection head 300 through the head driving unit 400 as soon as the nozzle tip 322 is detected by the detection sensors PZE as being in contact with the stage 100.

In an example, the nozzle tip 322 may come into contact with the target substrate S even during the ejection of ink. In this example, the control device 700 can also adjust the position of the ejection head 300. In addition, the control device 700 can notify the user of the contact between the nozzle tip 322 and the target substrate S through the output device 800, enabling real-time detection of any scratches on the target substrate S. Accordingly, additional damage to other target substrates S can be prevented in subsequent processes, thereby increasing process efficiency.

In embodiments of the present invention, as illustrated in FIG. 7, the control device 700 may include a contact signal processing unit (or a contact signal processing circuit) 710 and a head driving control unit (or a head driving control circuit) 720.

The contact signal processing unit 710 may receive the contact signal CS from the detection sensors PZE. The contact signal CS may include information regarding the contact status of the nozzle tip 322. For example, the contact signal CS may refer to the voltage that is generated in the first and second electrodes E1 and E2 due to the contact between the nozzle tip 322 and other components. The contact signal processing unit 710 may generate a contact data signal CDS, which includes data regarding the contact intensity and position of the nozzle tip 322 based on the magnitude, frequency, and position of the contact signal CS. For example, the contact data signal CDS may include information regarding at least one of the contact intensity and the contact position of the nozzle tip 322.

The head driving control unit 720 may receive the contact data signal CDS from the contact signal processing unit 710. The head driving control unit 720 may generate a head driving control signal HCS using the contact data signal CDS to control the position of the ejection head 300.

Upon receiving the head driving control signal HCS from the head driving control unit 720, the head driving unit 400 may adjust the position of the ejection head 300 in response to the head driving control signal HCS.

In addition, the contact signal processing unit 710 may receive the contact signal CS from the detection sensors PZE and generate a contact output signal COS based on the contact signal CS.

The output device 800 may receive the contact output signal COS from the contact signal processing unit 710. The output device 800 may also receive image data signals IDS from the vision device 600. The image data signals IDS may include information regarding images of the stage 100 and the target substrate S, captured by the vision device 600.

The output device 800 may output images through a separate display device based on the image data signals IDS that are received from the vision device 600. The output device 800 may also output sounds through a separate sound device. For example, the images output by the output device 800 may include not only the images of the stage 100 and the target substrate S, but also light from warning lights, and the sounds output by the output device 800 may include warning sounds from the warning lights. Through the images and sounds that are output by the output device 800, the user can easily identify the status of contact between the nozzle tip 322 and the target substrate S.

Embodiments of the present invention will hereinafter be described, focusing on the distinctions from the previous embodiments. Consistent reference numerals are employed for corresponding components in both the specification and the drawings, with repetitive explanations for these components being omitted.

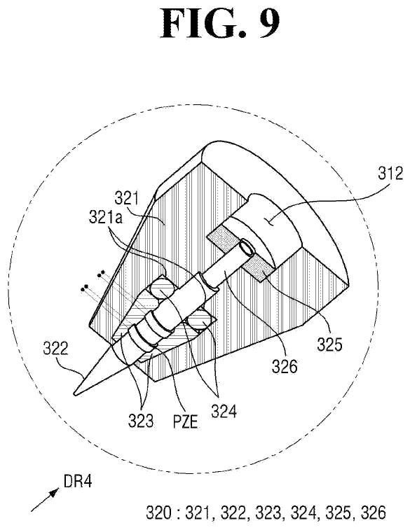

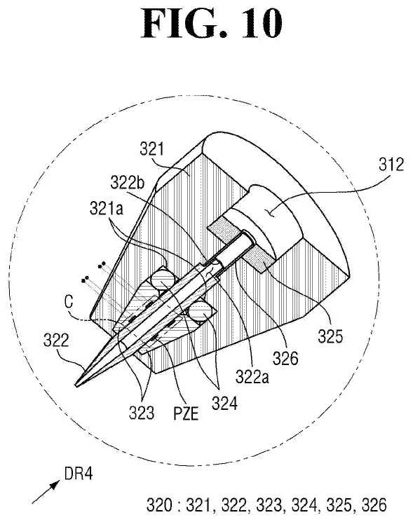

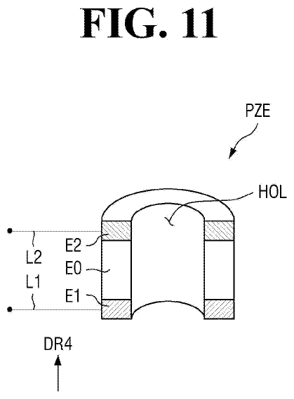

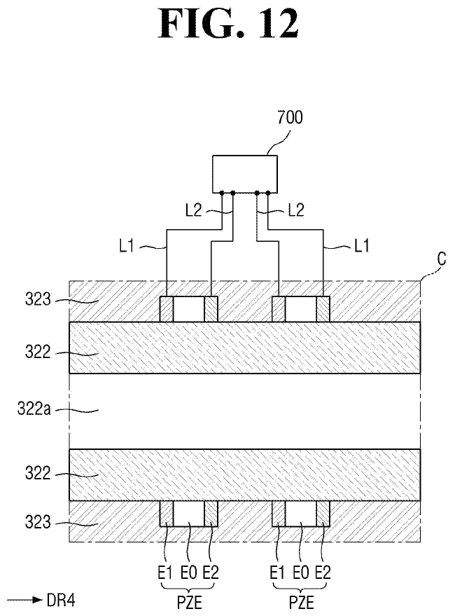

FIG. 9 is a cross-sectional perspective view of a nozzle part of an ejection head of an apparatus for manufacturing a display device according to an embodiment of the present invention. FIG. 10 is a cross-sectional view of the nozzle part of FIG. 9. FIG. 11 is a cross-sectional view of a detection sensor according to an embodiment of the present invention. FIG. 12 is a cross-sectional view of area C of FIG. 10.

The embodiment of FIGS. 9 through 12 differs from the embodiment of FIG. 3 in the direction in which the components of each detection sensor PZE are stacked.

Specifically, referring to FIGS. 9 through 12, detection sensors PZE may have an annular shape. For example, the detection sensors PZE may have a smaller thickness in a fourth direction DR4 than their counterpart of FIG. 3.

Each of the detection sensors PZE, like their counterpart of FIG. 3, may include a first electrode E1, a piezoelectric body E0, a second electrode E2, and a through hole HOL. The detection sensors PZE may have a different structure from their counterpart of FIG. 3.

As illustrated in FIG. 11, the second electrode E2 may be disposed on the piezoelectric body E0, and the piezoelectric body E0 may be disposed on the first electrode EL. For example, the piezoelectric body E0 may be disposed between the first electrode E1 and the second electrode E2 in a vertical direction. The first electrode E1, the piezoelectric body E0, and the second electrode E2 may be disposed to surround the through hole HOL. When a nozzle tip 322 is fastened into each of the detection sensors PZE, the first electrode E1, the piezoelectric body E0, and the second electrode E2 may be positioned to surround the nozzle tip 322.

The first electrode E1, the piezoelectric body E0, and the second electrode E2 may have the same outer diameter and the same inner diameter as one another, but the present invention is not limited thereto. In addition, the first electrode E1, the piezoelectric body E0, and the second electrode E2 may have different outer diameters and/or different inner diameters depending on the shape of the nozzle tip 322, which is disposed within the through hole HOL of each of the detection sensors PZE.

As illustrated in FIG. 12, the direction in which the first electrode E1, the piezoelectric body E0, and the second electrode E2 are stacked in each of the detection sensors PZE may be the same as the extension direction of the nozzle tip 322. For example, the first electrode E1, the piezoelectric body E0, and the second electrode E2 may be stacked in each of the detection sensors PZE in a direction that is parallel to a fourth direction DR4.

When external impacts are applied to the nozzle tip 322, the detection sensors PZE may sense pressure changes resulting from the external impacts. The detection sensors PZE may detect the pressure applied to the nozzle tip 322 along the stacking direction of the first electrode E1, the piezoelectric body E0, and the second electrode E2 in each of the detection sensors PZE. For example, the detection sensors PZE may detect pressure that is applied to the nozzle tip 322 along the fourth direction DR4. The thickness of the piezoelectric body E0 of each of the detection sensors PZE may undergo changes due to the pressure that is applied along the stacking direction of the first electrode E1, the piezoelectric body E0, and the second electrode E2 in each of the detection sensors PZE. Such thickness variations may lead to the generation of positive and negative voltages in the first and second electrodes E1 and E2, respectively, within each of the detection sensors PZE. The positive voltage generated in the first electrode E1 of each of the detection sensors PZE may be transmitted to a control device 700 through a first line L1, while the negative voltage generated in the second electrode E2 of each of the detection sensors PZE may be transmitted to the control device 700 through a second line L2.

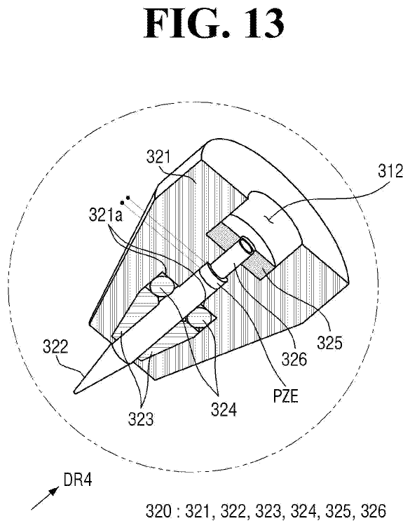

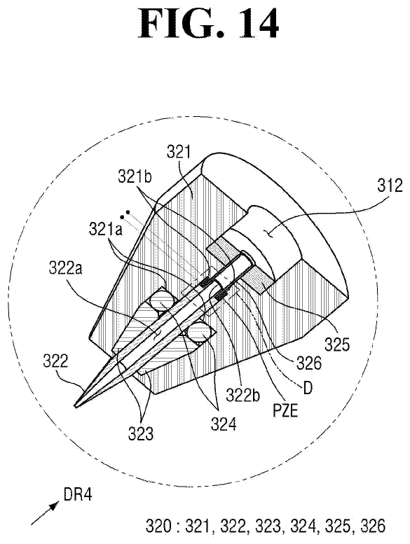

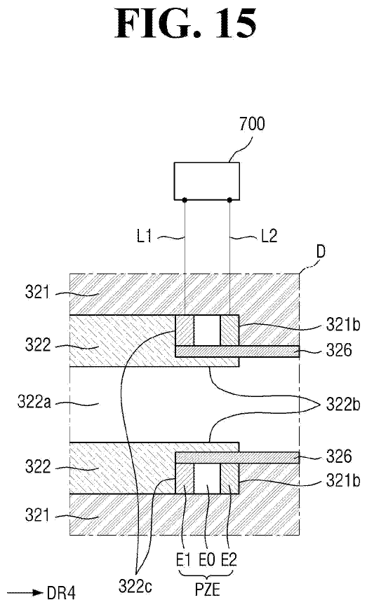

FIG. 13 is a cross-sectional perspective view of a nozzle part of an ejection head of an apparatus for manufacturing a display device according to an embodiment of the present invention. FIG. 14 is a cross-sectional view of a nozzle part of an ejection head of an apparatus for manufacturing a display device according to an embodiment of the present invention. FIG. 15 is a cross-sectional view of area D of FIG. 14.

The embodiment of FIGS. 13 through 15 differs from the embodiment of FIG. 9 in the position of detection sensors PZE.

Referring to FIGS. 13 through 15, the detection sensors PZE may be interposed between a nozzle tip 322 and a second housing 321 in the extension direction of the nozzle tip 322. For example, the detection sensors PZE may be disposed adjacent to a first-side end portion, in the fourth direction DR4, of the nozzle tip 322.

The nozzle tip 322 may include a coupling portion 322b and second stepped portions 322c, which are disposed in the first-side end portion of the nozzle tip 322.

In embodiments of the present invention, the coupling portion 322b may protrude from the first-side end portion of the nozzle tip 322 toward a first side in the fourth direction DR4. The outer diameter of the coupling portion 322b may be smaller than the outer diameter of the nozzle tip 322. The coupling portion 322b may be surrounded by a first nozzle tube 326. The coupling portion 322b may be inserted into the first nozzle tube 326.

The second stepped portions 322c may be disposed on a second side, in the fourth direction DR4, of the coupling portion 322b. As illustrated in FIG. 15, in a cross-sectional view taken along the fourth direction DR4, the second stepped portions 322c may extend in a direction perpendicular to the fourth direction DR4.

The second housing 321 may include third stepped portions 321b, which are opposite to the second stepped portions 322c of the nozzle tip 322.

The detection sensors PZE may be disposed within the spaces defined by the coupling portion 322b and the second stepped portions 322c of the nozzle tip 322 and the third stepped portions 321b of the second housing 321. For example, the detection sensors PZE may be disposed between the coupling portion 322b, the second stepped portions 322c, and the third stepped portions 321b. For example, as illustrated in FIG. 15, in a cross-sectional view taken along the fourth direction DR4, rectangular spaces may be defined by the coupling portion 322b and the second stepped portions 322c of the nozzle tip 322 and the third stepped portions 321b of the second housing 321. Within these rectangular spaces, the detection sensors PZE may be interposed between the nozzle tip 322 and the second housing 321 in the fourth direction DR4. In this case, the detection sensors PZE may be disposed to surround the coupling portion 322b and the first nozzle tube 326.

In each of the detection sensors PZE, a first electrode E1, a piezoelectric body E0, and a second electrode E2 may be sequentially arranged in the fourth direction DR4. The first electrode E1 may be disposed adjacent to the second stepped portions 322c of the nozzle tip 322, and the second electrode E2 may be disposed adjacent to the third stepped portions 321b of the second housing 321.

As the detection sensors PZE are interposed between the nozzle tip 322 and the second housing 321 in the extension direction of the nozzle tip 322, the detection sensors PZE can effectively detect the pressure that is applied to the nozzle tip 322 along the fourth direction DR4. For example, when pressure is applied to the nozzle tip 322 along the fourth direction DR4, the detection sensors PZE, which are interposed between the second stepped portions 322c of the nozzle tip 322 and the third stepped portions 321b of the second housing 321, can effectively detect the pressure that is applied along the fourth direction DR4, due to the reaction of the second stepped portions 322c of the nozzle tip 322 and the third stepped portions 321b of the second housing 321.

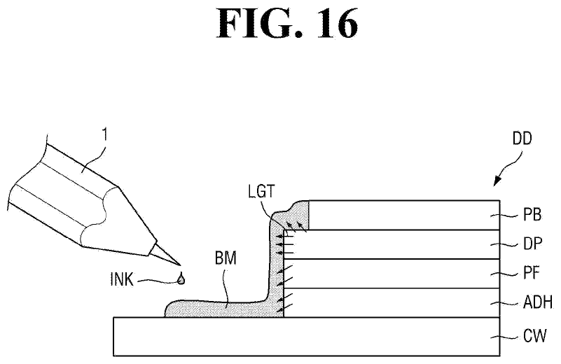

FIG. 16 is a cross-sectional perspective view illustrating how to manufacture a display device by using an apparatus for manufacturing a display device according to an embodiment of the present invention.

Referring to FIG. 16, a display device DD, which is a device capable of displaying videos and still images, may be used as a display screen for portable electronic devices such as mobile phones, smartphones, tablet personal computers (PCs), smartwatches, watch phones, mobile communication terminals, electronic notepads, e-book readers, portable multimedia players (PMPs), navigational devices, ultra mobile PCs (UMPCs), as well as other various products such as televisions (TVs), laptops, monitors, advertising boards, and Internet of Things (IoT) devices. The display device DD may be any one of an organic light-emitting display, an LCD device, a plasma display device, a field emission display device, an electrophoretic display device, an electrowetting display, a quantum-dot luminescent display device, and/or a micro LED display device.

The display device DD may include a display panel DP, a polarizing film PF, an adhesive member ADH, a cover window CW, and a panel bottom cover PB.

The display panel DP may provide a display screen for displaying images. For example, the display panel DP may be an organic light-emitting display panel, a micro LED display panel, a nano LED display panel, a quantum-dot luminescent display panel, an LCD panel, a plasma display panel, an electroluminescent display panel, an electrophoretic display panel, or an electrowetting display panel.

In embodiments of the present invention, the display panel DP may include a substrate, a display layer, which includes light-emitting elements and circuits to drive the light-emitting elements, an encapsulation layer for preventing the penetration of oxygen or moisture into the display layer, and a sensor electrode layer for detecting touch input from a user.

The polarizing film PF may be disposed on a first surface of the display panel DP. The polarizing film PF can reduce external glare reflection. For example, the polarizing film PF may include a first base material, a linear polarizer, a phase delay film, such as a V/4 plate (or a quarter-wave plate), and a second base material. The first base material, the phase delay film, the linear polarizer, and the second base material of the polarizing film PF can be sequentially stacked on the display panel DP.

The cover window CW may be disposed on the polarizing film PF. The cover window CW may possess transparency to allow light generated from the display panel DP to pass therethrough. The cover window CW may be formed of glass or plastic. In embodiments of the present invention, the cover window CW may include chemically strengthened glass. In addition, in embodiments of the present invention, the cover window CW may include a polyimide (PI) film.

The adhesive member ADH may attach the polarizing film PF and the cover window CW to each other. In embodiments of the present invention, the adhesive member ADH may be a pressure-sensitive adhesive (PSA), an optical clear adhesive (OCA), or an optical clear resin (OCR).

The panel bottom cover PB may be disposed on a second surface of the display panel DP. The panel bottom cover PB may be attached to the second surface of the display panel DP via an adhesive material such as PSA.

The panel bottom cover PB may include at least one of the following: a light-shielding member for absorbing incoming light from the outside; a buffer member for absorbing external impacts; and a heat dissipation member for efficiently dissipating heat that is generated by the display panel DP.

The display device DD may further include a light-shielding member BM, which is disposed on the sides of the display device DD.

The light-shielding member BM may be disposed along the edges of the display device DD. For example, the light-shielding member BM may be disposed along the edges of the display panel DP, the polarizing film PF, the adhesive member ADH, and the panel bottom cover PB.

The light-shielding member BM may prevent light LGT from leaking outwards from the display device DD. The light-shielding member BM may include a light-shielding material. For example, the light-shielding member BM may include an organic black pigment (such as black carbon particles) and/or light-shielding metallic particles.

The light-shielding member BM of the display device DD may be formed by the apparatus 1 according to any one of the aforementioned embodiments. The apparatus 1 may eject ink “INK” along the periphery of the display device DD. The ink “INK” may solidify to form the light-shielding member BM.

The apparatus 1 may be used to form the light-shielding member BM, but the present invention is not limited thereto. For example, the apparatus 1 may also be used to form other members or components of the display device DD. For example, the apparatus 1 may also be used to apply the adhesive member ADH, coat the panel bottom cover PB, or apply an organic material to form the light-emitting elements within the display panel DP.

While the present invention has been described with reference to the embodiments thereof, it will be understood by those of ordinary skill in the art that various changes in form and detail may be made thereto without departing from the spirit and scope of the present invention.

What is claimed is:

1. An apparatus for manufacturing a display device, comprising:
a stage;
an ejection head overlapping the stage, wherein the ejection head comprises a main body part and a nozzle part, wherein the main body part houses ink, and the nozzle part comprises a nozzle tip and a first housing surrounding the nozzle tip; and
a detection sensor interposed between the nozzle tip and the first housing.

2. The apparatus of claim 1, wherein the detection sensor surrounds the nozzle tip.

3. The apparatus of claim 2, wherein the detection sensor is interposed between the nozzle tip and the first housing in a direction different from an extension direction of the nozzle tip.

4. The apparatus of claim 1, wherein the detection sensor is disposed outside of the main body part.

5. The apparatus of claim 1, wherein the detection sensor has an annular shape.

6. The apparatus of claim 1, wherein the detection sensor is pressure sensor.

7. The apparatus of claim 6, wherein the detection sensor comprises a first electrode, a second electrode, and a piezoelectric body disposed between the first and second electrodes.

8. The apparatus of claim 7, wherein
the second electrode surrounds the piezoelectric body, and
the piezoelectric body surrounds the first electrode.

9. The apparatus of claim 8, wherein a direction in which the first electrode, the piezoelectric body, and the second electrode are stacked is perpendicular to an extension direction of the nozzle tip.

10. The apparatus of claim 7, wherein the direction in which the first electrode, the piezoelectric body, and the second electrode are stacked is the same as the extension direction of the nozzle tip.

11. The apparatus of claim 1, further comprising:
a head driver moving the ejection head; and
a controller controlling an operation of the ejection head,
wherein the control device comprises:
a signal processing circuit receiving a first signal from the detection sensor; and
a driving control circuit receiving a second signal from the signal processing unit, and
wherein the driving control circuit provides a third signal to the head driving unit.

12. The apparatus of claim 11, wherein the first signal includes information regarding a contact status of the nozzle tip with an object.

13. The apparatus of claim 12, wherein the second signal includes information regarding at least one of a contact position or contact intensity of the nozzle tip.

14. The apparatus of claim 13, wherein the third signal is for controlling the ejection head.

15. The apparatus of claim 11, further comprising:
an output device receiving an output signal from the signal processing circuit,
wherein the output device outputs at least one of an image or sound upon receiving the output signal.

16. The apparatus of claim 15, further comprising:
an image sensor capturing an image of the ejection head,
wherein the output device receives an image data signal from the image sensor by receiving the output signal from the signal processing circuit.

17. The apparatus of claim 1, further comprising:
a first nozzle tube connecting the main body part and the nozzle part to each other,
wherein the nozzle tip comprises a coupling portion, which is coupled to the first nozzle tube.

18. The apparatus of claim 17, wherein
the nozzle part further comprises a sealing portion, which is disposed in a receiving portion of the main body part, and
the sealing portion surrounds the first nozzle tube.

19. The apparatus of claim 1, wherein
the nozzle part further comprises a first fixing portion, which is disposed between the first housing and the nozzle tip, and
the detection sensor is interposed between the first fixing portion and the nozzle tip.

20. An apparatus for manufacturing a display device, comprising:
an ejection head comprising a nozzle tip and a first housing, which surrounds the nozzle tip;
a detection sensor interposed between the nozzle tip and the first housing, wherein the detection sensor surrounds the nozzle tip; and
an ink supply line connected to the ejection head.
